(19) United States
(12) Patent Application Publication
(10) Pub. No.: US 2016/0132296 A1
(43) Pub. Date: May 12, 2016

(54) APPARATUS AND METHOD FOR GENERATING DIGITAL VALUE

(71) Applicant: ELECTRONICS AND TELECOMMUNICATIONS RESEARCH INSTITUTE, Daejeon (KR)

(72) Inventor: Seong-Cheon PARK, Seongnam (KR)

(21) Appl. No.: 14/938,772

(22) Filed: Nov. 11, 2015

(30) Foreign Application Priority Data
Nov. 11, 2014 (KR) 10-2014-0156381
Nov. 11, 2014 (KR) 10-2014-0156382
Oct. 6, 2015 (KR) 10-2015-0140593
Oct. 6, 2015 (KR) 10-2015-0140594

(51) Int. Cl. G06F 7/58; H01L 23/522; H03K 3/037; H01L 27/28; H01L 51/00; H01L 51/05; H01L 21/768

(52) U.S. Cl. CPC G06F 7/588; H01L 51/0558; H01L 23/5226; H01L 21/76802; H01L 27/283; H01L 51/0048; H03K 3/037; G06F 2207/58

(57) ABSTRACT

Provided is an apparatus for generating a digital value, including: an identification value generator including a plurality of unit cells; and an identification value extractor outputting an identification value of a plurality of bits by using output values of the plurality of unit cells, wherein each of the plurality of unit cells includes an identification value generating element including a first upper electrode and a second upper electrode formed on the same layer, and determines the output value according to electrical connection or cut-off of the first upper electrode and the second upper electrode.

### CROSS-REFERENCE TO RELATED APPLICATION

This application claims priority to and the benefit of Korean Patent Application Nos. 10-2014-0156381, 10-2014-0156382, 10-2015-0140593, and 10-2015-0140594 filed in the Korean Intellectual Property Office on Nov. 11, 2014, Nov. 11, 2014, Oct. 6, 2015, and Oct. 6, 2015, the entire contents of which are incorporated herein by reference.

### BACKGROUND OF THE INVENTION

(a) Field of the Invention

The present invention relates to an apparatus and a method for generating a digital value, and more particularly, to an apparatus and a method for generating a digital value by using a semiconductor process.

(b) Description of the Related Art

With the advance of an information-oriented society, the need for protection of personal privacy has also increased and a technology for constructing a security system that encrypts and decrypts information to safely transmit the encrypted and decrypted information has been settled as a key technology which is positively required.

Digital values include identification values, key values for information encrypting and decrypting, identification keys required for a digital signature and authentication, initialization vector values, session key values of communication, and the like are used for information security of an electronic apparatus, information security of an embedded system, information security of a system on a chip (SoC), information security of a smart card, information security of a Universal Subscriber Identity Module (USIM) card, information security of Machine to Machine (M2M) communication, information security of Internet of Things (IoT), Vehicle to Vehicle (V2V) communication of a smart vehicle, Vehicle to Infrastructure (V2I) communication, information security of In-Vehicle Network (IVN) communication, information security of a smart phone, and the like. Further, the digital values are used in various fields, which include identification values for Radio-Frequency Identification (RFID), random numbers used in a computer, random numbers used in sports or games, random numbers used in mathematics, science, and statistics, and the like.

A probability that bits of the digital values will be 1 and a probability that the bits of the digital values will be 0 need to be completely random in order for the digital values to be used for the information security, the generated digital values should not be changed even over time, and the generated values cannot be physically cloned, and as a result, the generated digital values should be robust against an external attack.

A method that uses a semiconductor process in order to randomly generate the digital values is proposed. A technology that generates the digital values through the semiconductor process includes a scheme using randomness of an initial value of an SRAM, a scheme extracting an identification value by comparing variations of electrical characteristic values of a semiconductor depending on a deviation of the process, and a scheme generating a random number value by a short-circuit of a circuit through designing the size of a via positioned between conductive layers to be small by intentionally violating a semiconductor design rule.

However, the schemes generating the digital values by using the semiconductor process are limited in that a complicated circuit needs to be designed or the random number value needs to be generated by intentionally violating the design rule.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide an apparatus and a method for generating a digital value which can secure true randomness and time invariance even by not violating a design rule without designing a complicated circuit and that cannot be physically cloned.

An exemplary embodiment of the present invention provides an apparatus for generating a digital value. The apparatus for generating a digital value includes an identification value generator and an identification value extractor. The identification value generator includes a plurality of unit cells. The identification value extractor outputs identification values of a plurality of bits by using output values of the plurality of unit cells. In this case, each of the plurality of unit cells includes an identification value generating element including a first upper electrode and a second upper electrode formed on the same layer, and determines the output value according to electrical connection or cut-off of the first upper electrode and the second upper electrode.

The electrical connection or cut-off may be determined by a difference in etching depth between the via holes formed in the lower direction of the first upper electrode and the second upper electrode through etching, respectively.

The identification value generating element may include a first insulating layer formed on a substrate, a second lower electrode formed on the first insulating layer, a second insulating layer formed on the second lower electrode, a first lower electrode formed on the second insulating layer, a third insulating layer formed on the first lower electrode, a first via hole and a second via hole formed in the lower direction of the third insulating layer with set depths, respectively, through an etching process, a first via and a second via formed by filling the first via hole and the second via hole with conductors, respectively, and the first upper electrode and the second upper electrode are formed on the first via and the second via.

The first via hole and the second via hole may be formed with different depths through the etching process.

When both the first via and the second via reach locations of the second lower electrode, the first upper electrode and the second upper electrode are electrically connected, and when only one of the first via and the second via reaches the first lower electrode or the second lower electrode, the first upper electrode and the second upper electrode are electrically cut off.

Some of the plurality of unit cells may include identification value generating elements in which the first upper electrode and the second upper electrode are electrically connected, and the residual of the plurality of unit cells may include identification value generating elements in which the first upper electrode and the second upper electrode are electrically cut off.

The identification value generating element may further include a carbon nanotube layer formed to connect the first upper electrode and the second upper electrode, and the electrical connection or cut-off may be determined by the carbon nanotube layer.

The carbon nanotube layer may include a single carbon nanotube or a carbon nanotube bundle.

The first upper electrode and the second upper electrode may be formed by one of a P-type semiconductor, an N-type semiconductor, and a conductive material.

The identification value generating element may further include an insulating layer formed on the substrate and having the first upper electrode and the second upper electrode formed on the top thereof to be spaced apart from each other, and a control electrode formed on an insulating layer on the carbon nanotube layer or formed on the substrate.

Each of the plurality of unit cells may include an oscillating circuit outputting a square wave frequency as the output value by using the identification value generating element as a capacitor.

The identification value extractor may include a sampler outputting a plurality of binary digital values by sampling square wave frequencies output from the plurality of unit cells, respectively, at a desired time, and an output unit outputting the identification values of the plurality of bits from the plurality of binary digital values.

The sampler may include a plurality of D flip-flops receiving the square wave frequencies output from the plurality of unit cells, respectively, as inputs, and outputting 0 or 1 from a value of a square wave frequency when a clock signal is applied.

Each of the plurality of unit cells may include: the identification value generating element connected between a first voltage source supplying a first voltage and a second voltage source supplying a second voltage lower than the first voltage; and an output node outputting 0 or 1 as the output value according to the electrical connection or cut-off of the identification value generating element, and the first upper electrode may be connected to the first voltage source, the second upper electrode may be connected to the second voltage source, and the output node may be connected to the first upper electrode or the second upper electrode.

Another exemplary embodiment of the present invention provides an apparatus for generating a digital value. The apparatus for generating a digital value includes a plurality of identification value processors and a true random number extractor. The plurality of identification value processors include a plurality of unit cells, respectively, and output identification values of a plurality of bits through output values of the plurality of unit cells. The true random number extractor extracts true random numbers by using the plurality of identification values output from the plurality of identification value processors, respectively, and outputs the extracted true random numbers. In this case, each of the plurality of unit cells includes an identification value generating element determining the output value according to electrical connection or cut-off of a first upper electrode and a second upper electrode formed on the same layer

The identification value generating element may include: a first insulating layer formed on a substrate; a second lower electrode formed on the first insulating layer; a second insulating layer formed on the second lower electrode; a first lower electrode formed on the second insulating layer; a third insulating layer formed on the first lower electrode; a first via hole and a second via hole formed in the lower direction of the third insulating layer with set depths, respectively, through an etching process; and a first via and a second via formed by filling the first via hole and the second via hole with a conductor, respectively, wherein the first upper electrode and the second upper electrode are formed on the first via and the second via, and the first via hole and the second via hole may be formed with different depths through the etching process.

The identification value generating element may include: an insulating layer formed on the substrate and having the first upper electrode and the second upper electrode formed on the top thereof to be spaced apart from each other; a carbon nanotube layer formed to connect the first upper electrode and the second upper electrode on the insulating layer and including a single carbon nanotube or a carbon nanotube bundle; and a control electrode formed on an insulating layer on the carbon nanotube layer or formed on the substrate.

The first upper electrode and the second upper electrode may be formed by one of a P-type semiconductor, an N-type semiconductor, and a conductive material.

Yet another exemplary embodiment of the present invention provides a method for generating a digital value in a digital value generating apparatus. The method for generating a digital value may include: generating a plurality of output values by using a plurality of unit cells including identification value generating elements determining output values according to electrical connection or cut-off between a first upper electrode and a second upper electrode formed on the same layer; and outputting identification values of a plurality of bits by using the plurality of output values, wherein the electrical connection or cut-off is determined by a difference in etching depth between the via holes formed in the lower direction of the first upper electrode and the second upper electrode through etching, respectively, or a carbon nanotube layer formed to connect the first upper electrode and the second upper electrode.

The method for generating a digital value may further include: generating a plurality of identification values of the plurality of bits; and extracting a true random number of a predetermined bit by using the plurality of identification values.

### BRIEF DESCRIPTION OF THE DRAWINGS

FIG. 1 is a diagram illustrating an apparatus for generating a digital value according to an exemplary embodiment of the present invention.

FIG. 2 is a block diagram illustrating an identification value generating element according to an exemplary embodiment of the present invention.

Each of FIGS. 3 to 6 is a diagram illustrating one example of the depth of a via hole.

Each of FIGS. 7 to 10 is a diagram illustrating one example of the identification value generating element formed by using the via holes illustrated in FIGS. 3 to 6.

Each of FIGS. 11 and 12 is a diagram illustrating a property depending on chirality of a carbon nanotube according to the exemplary embodiment of the present invention.

FIG. 13 is a diagram illustrating a bundle of carbon nanotubes according to the exemplary embodiment of the present invention.

Each of FIGS. 14 and 15 is a diagram illustrating an identification value generating element according to another exemplary embodiment of the present invention.

Each of FIGS. 16 and 17 is a diagram illustrating an identification value generating element according to yet another exemplary embodiment of the present invention.

Each of FIGS. 18 and 19 is a diagram illustrating a unit cell according to an exemplary embodiment of the present invention.

FIG. 20 is a diagram illustrating a unit cell according to another exemplary embodiment of the present invention.

FIG. 21 is a diagram illustrating an identification value extractor according to an exemplary embodiment of the present invention.

FIG. 22 is a diagram illustrating an identification value extractor according to another exemplary embodiment of the present invention.

FIG. 23 is a diagram illustrating one example of a variable frequency extracting apparatus which can be implemented by using an identification value generator according to the exemplary embodiment of the present invention.

FIG. 24 is a diagram illustrating an apparatus for generating a digital value according to another exemplary embodiment of the present invention.

FIG. 25 is a flowchart illustrating a method for generating a digital value according to an exemplary embodiment of the present invention.

FIG. 26 is a flowchart illustrating a method for generating a digital value according to another exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

Throughout the specification and the claims, In addition, unless explicitly described to the contrary, the word “comprise” and variations such as “comprises” or “comprising” will be understood to imply the inclusion of stated elements but not the exclusion of any other elements.

An apparatus and a method for generating a digital value according to exemplary embodiments of the present invention will now be described in detail with reference to the accompanying drawings.

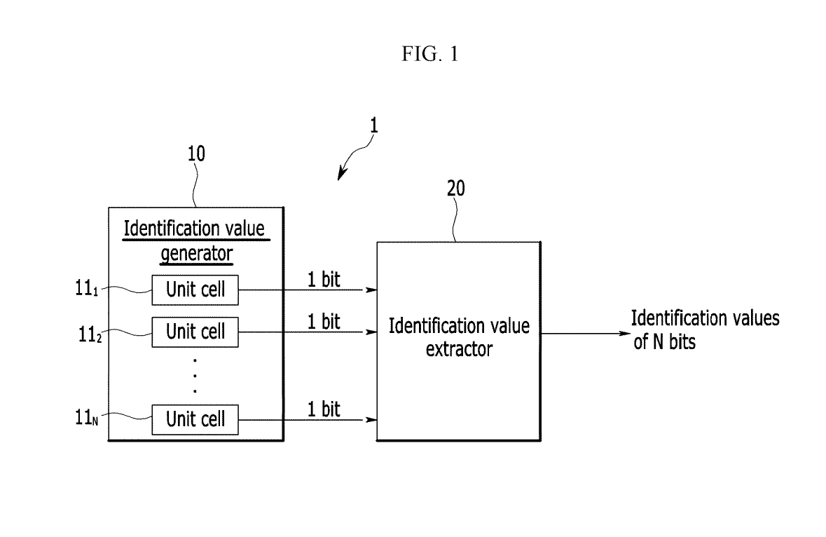

FIG. 1 is a diagram illustrating an apparatus for generating a digital value according to an exemplary embodiment of the present invention.

Referring to FIG. 1, the digital value generating apparatus 1 includes an identification value generator 10 and an identification value extractor 20.

The identification value generator 10 includes a plurality of unit cells 11₁ to 11_{N}, and outputs a plurality of digital bits output from the plurality of unit cells 11₁ to 11_{N}, respectively, to the identification value extractor 20. Each of the plurality of unit cells 11₁ to 11_{N} may generate a digital value of 1 bit. Each of the plurality of unit cells 11₁ to 11_{N} may generate a binary digital value of 0 or 1 through electrical conduction or cut-off of an identification value generating element. The identification value generating element according to the exemplary embodiment of the present invention may be generated by using a semiconductor etching process or a property of a carbon nanotube.

The identification value extractor 20 receives digital values output from the plurality of unit cells 11₁ to 11_{N} of the identification value generator 10, respectively, as inputs to output identification values of N bits by using the plurality of digital bits.

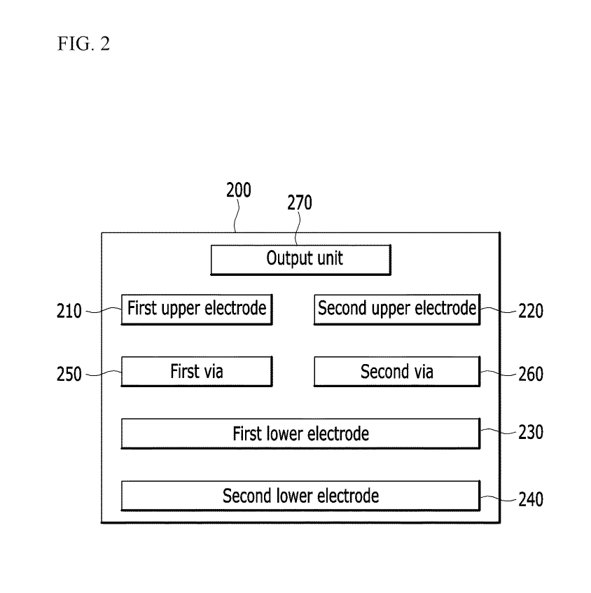

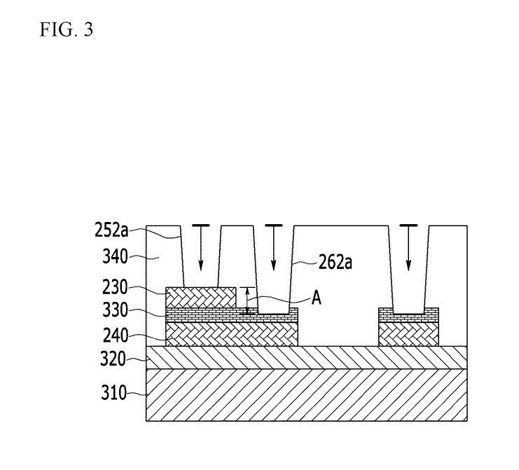

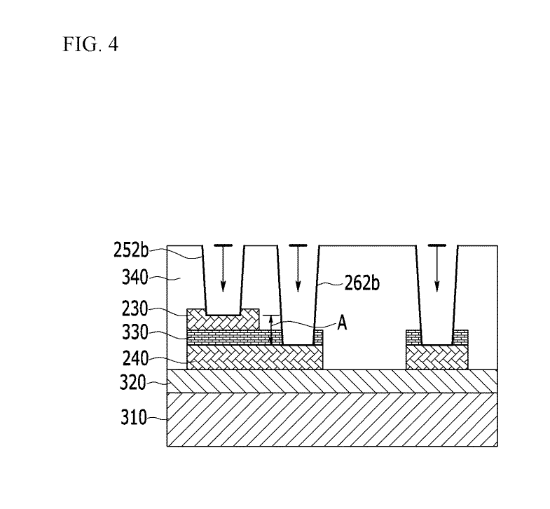

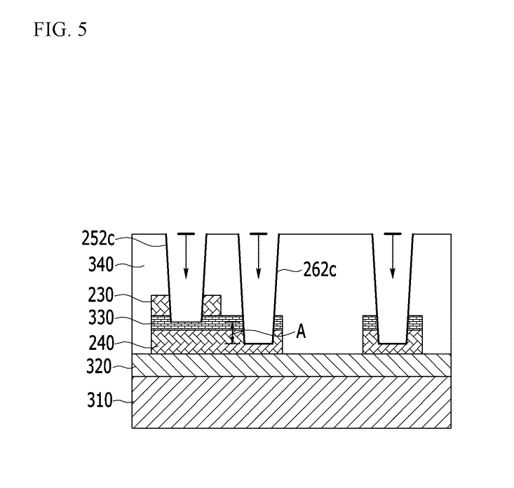

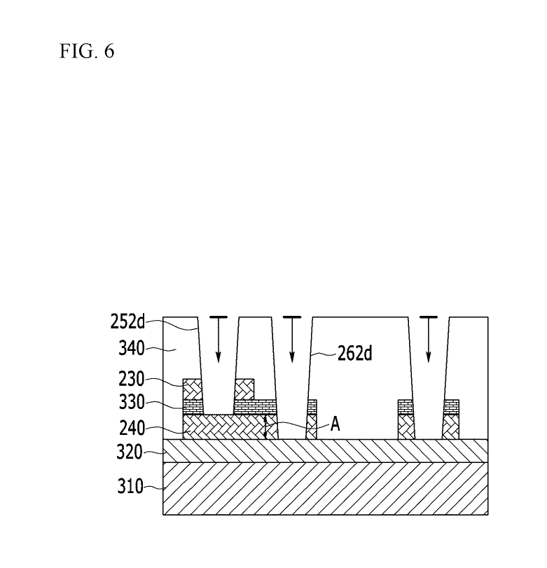

First, the identification value generating element using the semiconductor etching process will be described in detail with reference to FIGS. 2 to 10.

FIG. 2 is a block diagram illustrating an identification value generating element according to an exemplary embodiment of the present invention.

Referring to FIG. 2, the identification value generating element 200 includes a first upper electrode 210, a second upper electrode 220, a plurality of lower electrodes, for example, a first lower electrode 230 and a second lower electrode 240, a first via 250, a second via 260, and an output unit 270.

The first upper electrode 210 and the second upper electrode 220 are formed on the same layer, and the binary digital value of 0 or 1 is generated according to whether the first upper electrode 210 and the second upper electrode 220 are electrically conducted or cut off through the first via 250 and the second via 260.

The first lower electrode 230 and the second lower electrode 240 are positioned below the first upper electrode 210 and the second upper electrode 220 and formed on different layers. An insulating layer is positioned between the first lower electrode 230 and the second lower electrode 240. Further, the insulating layer is positioned even between the first and second upper electrodes 210 and the lower electrode 230. In FIG. 2, the first lower electrode 230 and the second lower electrode 240 are illustrated for easy description, but more lower electrodes may be formed on different layers.

The first via 250 is formed by filling the via hole formed on the lower of the first upper electrode 210 with a conductor and connected with the first upper electrode 210.

The second via 260 is formed by filling the via hole formed on the lower of the second upper electrode 220 with the conductor and connected with the second upper electrode 210.

The depths of the first via 250 and the second via 260 are set to be different from each other.

When both the first via 250 and the second via 260 reach the second lower electrode 240, the first upper electrode 210 and the second upper electrode 220 are electrically connected through the first via 250 and the second via 260. On the contrary, when the first via 250 and the second via 260 reach the lower electrode or the insulating layer formed on different layers, the first upper electrode 210 and the second upper electrode 220 are electrically cut off.

The output unit 270 generates the binary digital value of 0 or 1 according to whether the first upper electrode 210 and the second upper electrode 220 are electrically connected or cut off and outputs the generated binary digital value.

Each of FIGS. 3 to 6 is a diagram illustrating one example of the depth of the via hole.

Referring to FIGS. 3 to 6, an insulating layer 320 is formed on a substrate 310 and the second lower electrode 240 is formed on the insulating layer 320. An insulating layer 330 is formed on the second lower electrode 240 and the first lower electrode 230 is formed on the insulating layer 330. An insulating layer 340 is formed on the first lower electrode 230. In addition, via holes 252a, 252b, 252c, and 252d of the first via 250 for connection with the first upper electrode 210 are formed up to a predetermined depth through an etching process, and via holes 262a, 262b, 262c, and 262d of the second via 260 for connection with the second upper electrode 220 are formed up to a predetermined depth through the etching process. In this case, the via holes (252a and 262a of FIGS. 3, 252b and 262b of FIGS. 4, 252c and 262c of FIG. 5, and 252d and 262d of FIG. 6) are formed with different depths. That is, via holes (252a and 262a of FIGS. 3, 252b and 262b of FIGS. 4, 252c and 262c of FIG. 5, and 252d and 262d of FIG. 6) have set depth differences. As such, even though the depth differences among the via holes (252a and 262a of FIGS. 3, 252b and 262b of FIGS. 4, 252c and 262c of FIG. 5, and 252d and 262d of FIG. 6) are set, a variation may occur in the depth difference by various causes in the etching process.

For example, the depth differences of the via holes (252a and 262a of FIGS. 3, 252b and 262b of FIGS. 4, 252c and 262c of FIG. 5, and 252d and 262d of FIG. 6) may be set to A, and as illustrated in FIGS. 3 to 6, the vias 250 and 260 having various depths may be formed, which allows the depth differences among the via holes (252a and 262a of FIGS. 3, 252b and 262b of FIGS. 4, 252c and 262c of FIG. 5, and 252d and 262d of FIG. 6) to be formed as large as A by the etching process.

Referring to FIG. 3, the etching process is performed in a lower direction on the insulating layer 340. The bottom surface of the via hole 252a may reach up to the top of the first lower electrode 230 by the etching process, and the bottom surface of the via hole 262a may reach the inside of the insulating layer 330 by the depth difference as large as A from the bottom surface of the via hole 252a.

Further, referring to FIG. 4, the bottom surface of the via hole 252b may reach up to the inside of the first lower electrode 230 by the etching process, and the bottom surface of the via hole 262b may reach the top of the second lower electrode 240 by the depth difference as large as A from the bottom surface of the via hole 252b.

Unlike this, referring to FIG. 5, the bottom surface of the via hole 252c may reach up to the inside of the insulating layer 330 through the first lower electrode 230 by the etching process, and the bottom surface of the via hole 262c may reach the inside of the second lower electrode 240 by the depth difference as large as A from the bottom surface of the via hole 252c.

Further, as illustrated in FIG. 6, the bottom surface of the via hole 252d may reach up to the top of the second lower electrode 240 through the first lower electrode 230 and the insulating layer 330 by the etching process, and the bottom surface of the via hole 262d may reach the inside of the second lower electrode 240 by the depth difference as large as A from the bottom surface of the via hole 252d.

As such, the vias 250 and 260 having various depths may be generated by the etching process.

Each of FIGS. 7 to 10 is a diagram illustrating one example of the identification value generating element formed by using the via holes illustrated in FIGS. 3 to 6.

Referring to FIG. 7, when the via holes 252a and 262a formed as illustrated in FIG. 3 are filled with the conductor, the vias 250 and 260 are formed and the first upper electrode 210 and the second upper electrode 220 are formed on the vias 250 and 260, respectively. In addition, the first upper electrode 210 and the second upper electrode 220 may include connection members 211 and 221 for connection with voltage sources, respectively.

Since the via 250 is formed between the first upper electrode 210 and the top of the first lower electrode 230 and the via 260 is formed between the second upper electrode 220 and the inside of the insulating layer 330, the first upper electrode 210 and the second upper electrode 220 of the identification value generating element 200 are electrically cut off.

Referring to FIG. 8, the via holes 252b and 262b formed as illustrated in FIG. 4 are filled with the conductor, and as a result, the vias 250 and 260 are formed and the first upper electrode 210 and the second upper electrode 220 are formed on the vias 250 and 260, respectively. The via 250 is formed between the first upper electrode 210 and the inside of the first lower electrode 230 and the via 260 is formed between the second upper electrode 220 and the top of the second lower electrode 240. Therefore, the first upper electrode 210 and the second upper electrode 220 of the identification value generating element 200 are electrically cut off.

Referring to FIG. 9, the via holes 252c and 262c formed as illustrated in FIG. 5 are filled with the conductor, and as a result, the vias 250 and 260 are formed and the first upper electrode 210 and the second upper electrode 220 are formed on the vias 250 and 260, respectively. The via 250 is formed between the first upper electrode 210 and the inside of the insulating layer 330, and the via 260 is formed between the second upper electrode 220 and the inside of the second lower electrode 240. Therefore, the first upper electrode 210 and the second upper electrode 220 of the identification value generating element 200 are electrically cut off.

Meanwhile, referring to FIG. 10, the via holes 252d and 262d formed as illustrated in FIG. 6 are filled with the conductor, and as a result, the vias 250 and 260 are formed and the first upper electrode 210 and the second upper electrode 220 are formed on the vias 250 and 260, respectively. The via 250 is formed between the first upper electrode 210 and the top of the second lower electrode, and the via 260 is formed between the second upper electrode 220 and the inside of the second lower electrode 240. Therefore, the first upper electrode 210 and the second upper electrode 220 of the identification value generating element 200 are electrically connected, unlike FIGS. 7 to 9.

The identification value generating element 200 illustrated in FIGS. 7 to 10 is an example for easy description, and more various identification value generating elements 200 having the depth difference between the vias 250 and 260 may be formed and the identification value generating elements 200 formed as such may be used as identification value generating elements of N unit cells 11₁ to 11_{N}.

Next, the identification value generating element using the carbon nanotube will be described in detail with reference to FIGS. 11 to 17.

Each of FIGS. 11 and 12 is a diagram illustrating a property depending on chirality of the carbon nanotube according to the exemplary embodiment of the present invention.

As illustrated in FIG. 11, when carbon is arrayed in a zigzag pattern, the carbon nanotube has a semiconductor property in which the carbon nanotube is not normally conducted.

Meanwhile, as illustrated in FIG. 12, when carbon is arrayed in an armchair pattern, the carbon nanotube has a conductor property in which the carbon nanotube is normally conducted.

That is, the carbon nanotube has the semiconductor property or the conductor property according to the chirality of the carbon nanotube.

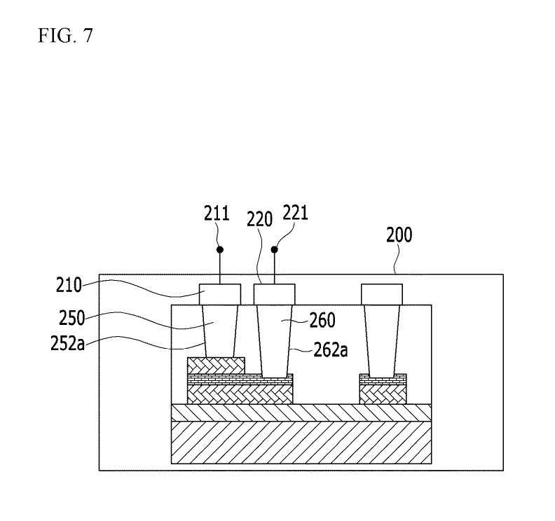

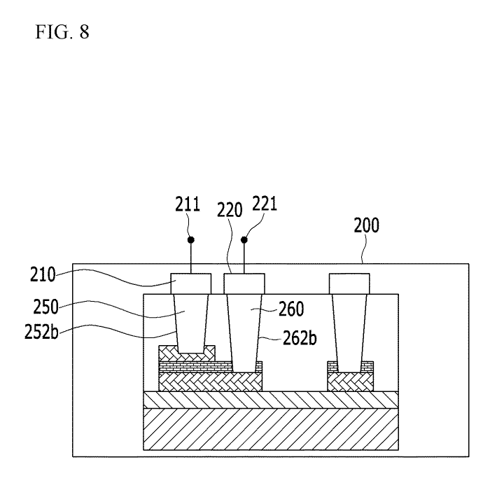

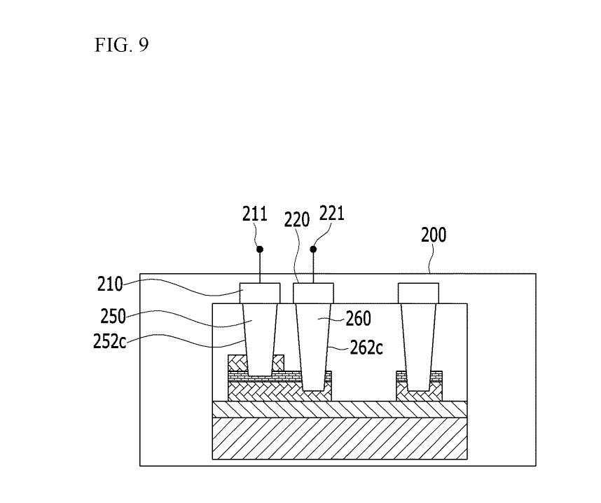

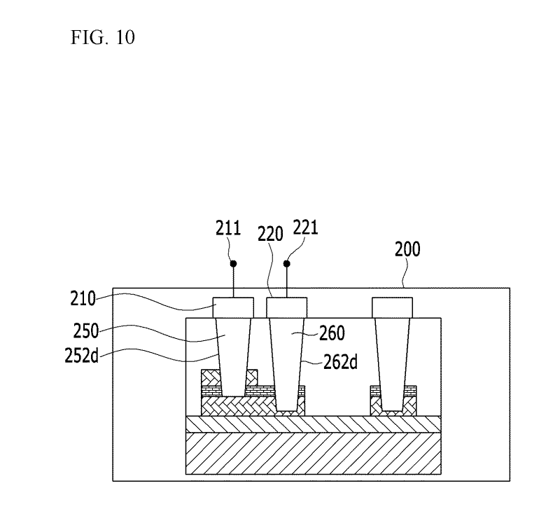

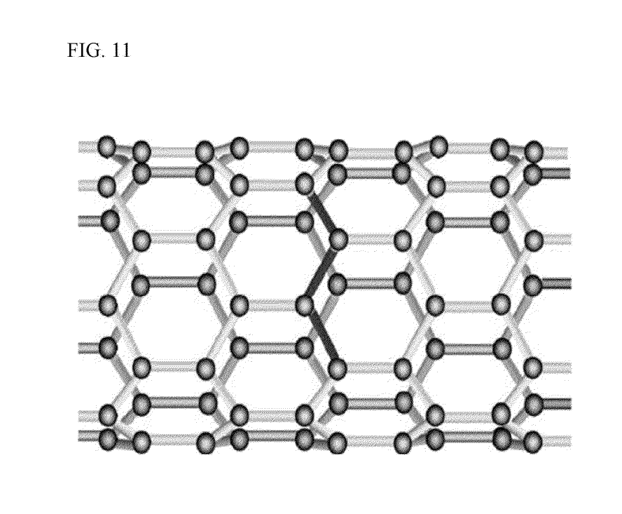

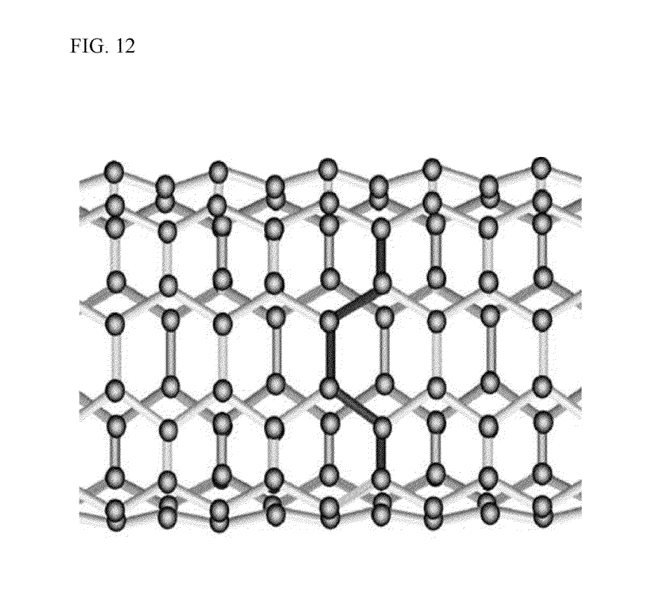

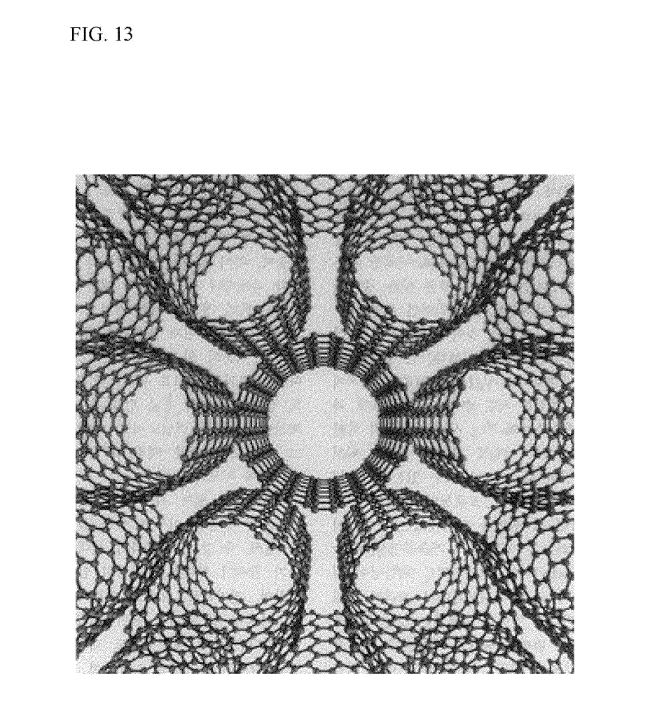

FIG. 13 is a diagram illustrating a bundle of the carbon nanotubes according to the exemplary embodiment of the present invention.

As illustrated in FIG. 13, when the carbon nanotubes randomly form the bundle, an electrical property may be changed by interaction of the carbon nanotubes. When the carbon nanotubes randomly form the bundle, the carbon nanotube bundle has an N-type or P-type semiconductor property. That is, when the carbon nanotubes have only the semiconductor property, the semiconductor property is a non-conductor property in which electricity is not normally conducted. However, when the carbon nanotube bundle has the N-type semiconductor property, a current flow by electrons may be generated, and when the carbon nanotube bundle has the P-type semiconductor property, a current flow by holes may be generated, and as a result, the carbon nanotubes may have a conductor property.

The digital value generating apparatus 1 according to the exemplary embodiment of the present invention may generate an identification value of N bits by using the property of the carbon nanotube.

Each of FIGS. 14 and 15 is a diagram illustrating an identification value generating element according to another exemplary embodiment of the present invention.

Referring to FIGS. 14 and 15, the identification value generating element 500/600 may be of a field effect transistor (FET) type. The FET type identification value generating element 500/600 includes a control electrode 510/610, a first upper electrode 520/620, a second upper electrode 530/630, and a carbon nanotube layer 540/640. In the FET type identification value generating element 500/600, the control electrode 510/610 corresponds to a gate electrode, the first upper electrode 520/620 corresponds to a drain electrode, and the second upper electrode 530/630 corresponds to a source electrode. Both the first upper electrode 520/620 and the second upper electrode 530/630 are generated as the N-type semiconductor or the P-type semiconductor.

Referring to FIG. 14, the control electrode 510 of the identification value generating element 500 is formed on a substrate, and an insulating layer 503 is formed on the control electrode 510. In this case, the substrate may be used as the control electrode. The first upper electrode 520 and the second upper electrode 530 are formed on the insulating layer 503 to be spaced apart from each other, and the carbon nanotube layer 540 is formed on the insulating layer 503 to connect the first upper electrode 520 and the second upper electrode 530 spaced apart from each other. The control electrode 510, the first upper electrode 520, and the second upper electrode 530 may include connection members 511, 521, and 531 for connection with a voltage source or a signal source, respectively.

Unlike this, as illustrated in FIG. 15, the control electrode 610 of the identification value generating element 600 may be formed on the top of the carbon nanotube layer 640. That is, the first upper electrode 620 and the second upper electrode 630 are formed on an insulating layer 603 formed on a substrate 601 to be spaced apart from each other, and the carbon nanotube layer 640 is formed on the insulating layer 603 to connect the first upper electrode 620 and the second upper electrode 630 spaced apart from each other. In addition, the control electrode 610 is formed on an insulating layer 605 formed on the carbon nanotube layer 640. The control electrode 610, the first upper electrode 620, and the second upper electrode 630 may include connection members 611, 621, and 631 for connection with the voltage source or the signal source, respectively.

As described above, the identification value generating element 500/600 may be constituted as the FET type, or as a switch type as illustrated in FIGS. 16 and 17.

Each of FIGS. 16 and 17 is a diagram illustrating an identification value generating element according to yet another exemplary embodiment of the present invention.

Referring to FIGS. 16 and 17, the identification value generating element 700/800 may be the switch type. The switch type identification value generating element 700/800 includes a control electrode 710/810, a first upper electrode 720/820, a second upper electrode 730/830, and a carbon nanotube layer 740/840.

Referring to FIG. 16, the control electrode 710 of the identification value generating element 700 is formed on the substrate, and an insulating layer 703 is formed on the control electrode 710. The first upper electrode 720 and the second upper electrode 730 are formed on the insulating layer 703 to be spaced apart from each other, and the carbon nanotube layer 740 is formed on the insulating layer 703 to connect the first upper electrode 720 and the second upper electrode 730 spaced apart from each other. The first upper electrode 720 and the second upper electrode 730 correspond to a conductive metal, a contact, or a via, and the control electrode 710, the first upper electrode 720, and the second upper electrode 730 may include connection members 711, 721, and 731 for connection with the voltage source or the signal source, respectively.

Unlike this, as illustrated in FIG. 17, the control electrode 810 of the identification value generating element 800 may be formed on the top of the carbon nanotube layer 840. That is, the first upper electrode 820 and the second upper electrode 830 are formed on an insulating layer 803 formed on a substrate 801 to be spaced apart from each other, and the carbon nanotube layer 840 is formed on the insulating layer 803 to connect the first upper electrode 820 and the second upper electrode 830 spaced apart from each other. In addition, the control electrode 810 is formed on an insulating layer 805 formed on the carbon nanotube layer 840. Similarly, the control electrode 810, the first upper electrode 820, and the second upper electrode 830 may include connection members 811, 821, and 831 for connection with the voltage source or the signal source, respectively.

In addition, in FIGS. 14 to 17, the carbon nanotube layers 540, 640, 740, and 840 may include a single carbon nanotube or the carbon nanotube bundle.

As such, the digital value generating apparatus 1 generates the identification value of N bits through electrical connection or cut-off of the identification value generating elements 500, 600, 700, and 800 constituted by the carbon nanotube. In this case, since the identification value generating elements 500, 600, 700, and 800 are not changed as time passed or according to a use environment, the identification value of N bits is generated by the identification value generating elements 500, 600, 700, and 800, and once the identification value of N bits is generated, the generated identification value of N bits is absolutely not changed.

Each of FIGS. 18 and 19 is a diagram illustrating unit cells according to an exemplary embodiment of the present invention. In FIGS. 18 and 19, only unit cell 11₁ is illustrated, but the residual unit cells 11₂ to 11_{N} may be constituted in the same manner as or similarly to the unit cell 11₁.

Referring to FIGS. 18 and 19, the unit cell 11₁ includes an identification value generating element 111 and an output node 113. The unit cell 11₁ may further include a resistor R. The identification value generating element 111 may be constituted by one of the identification value generating elements 200 described in FIGS. 7 to 10. Further, the identification value generating element 111 may be constituted by one of the identification value generating elements 500 to 800 described in FIGS. 14 to 17.

Referring to FIG. 18, the identification value generating element 111 is connected between a reference voltage source VDD and one end of the resistor R, and the other end of the resistor R is connected to a ground voltage source GND. In detail, the first upper electrodes 210, 510, 610, 710, and 810 are connected to the reference voltage source VDD, and the second upper electrodes 220, 520, 620, 720, and 820 are connected to the resistor R connected to the ground voltage source GND. The second upper electrodes 220, 520, 620, 720, and 820 are connected to the output node 113. The output node 113 outputs 0 or 1 which is the binary digital value through electrical connection or cut-off between the first upper electrodes 210, 510, 610, 710, and 810 and the second upper electrodes 220, 520, 620, 720, and 820.

In the case of the identification value generating element 200 described in FIGS. 7 to 10, the electrical connection or cut-off between the first upper electrode 210 and the second upper electrode 220 is determined according to whether both the vias 250 and 260 having the depth difference reach the first lower electrode 230 or the second lower electrode 240, and as a result, 0 or 1 is determined. For example, when the identification value generating element 200 illustrated in FIG. 10 is used as the identification value generating element 111, the output node 113 outputs 1, and when the identification value generating elements 200 illustrated in FIGS. 7 to 9 are used as the identification value generating element 111, the output node 113 outputs 0.

Further, in the case of the identification value generating elements 500 to 800 described in FIGS. 14 to 17, the electrical connection or cut-off between the first upper electrodes 510, 610, 710, and 810 and the second upper electrodes 520, 620, 720, and 820 is determined by the single carbon nanotube or the carbon nanotube bundle of the carbon nanotube layers 540, 640, 740, and 840, and as a result, 0 or 1 is randomly determined.

Unlike this, as illustrated in FIG. 19, the resistor R is connected between the first upper electrodes 210, 510, 610, 710, and 810 and the reference voltage source VDD, the second upper electrodes 220, 520, 620, 720, and 820 may be connected to the ground voltage source GND, and the first upper electrodes 210, 510, 610, 710, and 810 may be connected to the output node 113.

As described in FIG. 1, the identification value generator 10 includes N unit cells 11₁ to 11_{N} in order to generate the identification value of N bits, and all of N unit cells 11₁ to 11_{N} may be constituted like the unit cells illustrated in FIG. 18, constituted by the unit cells illustrated in FIG. 19, or constituted by mixing the unit cells illustrated in FIGS. 18 and 19.

In addition, the identification value generating element 111 of the unit cells 11₁ to 11_{N} may be constituted by one of the identification value generating elements 200 described in FIGS. 7 to 10 or one of the identification value generating elements 500 to 800 described in FIGS. 14 to 17.

When the identification value generating element 111 of the unit cells 11₁ to 11_{N} is generated by using the carbon nanotube layer, the conductor property, the semiconductor property, or the P-type or N-type semiconductor property of the carbon nanotube layer is randomly determined in each of N unit cells 11₁ to 11_{N}. Accordingly, the binary digital value which cannot be predicted is generated by the identification value generating element 111 of the unit cells 11₁ to 11_{N}, and after the binary digital value is generated, the value is fixed, and as a result, the value is appropriate to be used as the identification value. In this case, a material (a single carbon nanotube or carbon nanotube bundle) of the carbon nanotube layer of the identification value generating element 111 in each of N unit cells 11₁ to 11_{N} may be appropriately composed so that 0 and 1 are evenly shown in the identification value. In addition, the corresponding unit cell may output the binary bit value of 0 or 1 according to a physical phenomenon of the carbon nanotube layer of the identification value generating element 111.

Further, when the identification value generating element 111 of the unit cells 11₁ to 11_{N} is generated by using the semiconductor etching process, some of N unit cells 11₁ to 11_{N} may be constituted by the identification value generating element 200 described in FIG. 10 so that 1 and 0 are evenly shown in N unit cells 11₁ to 11_{N}, and the residual some unit cells may be constituted by the identification value generating elements 200 described in FIGS. 7 to 9. For example, the number of 1s among N binary digital values output from N unit cells 11₁ to 11_{N} is N/2, and when the number of 0s is N/2, 0 and 1 may be evenly shown in the identification value. Therefore, N unit cells 11₁ to 11_{N} may be designed so that a ratio of the identification value generating elements 200 in which the first upper electrode 210 and the second upper electrode 220 are electrically connected and a ratio of the identification value generating elements 200 in which the first upper electrode 210 and the second upper electrode 220 are electrically cut off in N unit cells 11₁ to 11_{N} are the same as each other in order to acquire the identification value of N bits in which 0 and 1 are even. In this case, it is determined whether the first upper electrode 210 and the second upper electrode 220 are electrically connected or cut off by the vias 250 and 260 having the depth difference by the etching process, but various other variables may be present.

For example, the variables may include the sizes of etching holes for forming the via holes (252a and 262a of FIGS. 3, 252b and 262b of FIGS. 4, 252c and 262c of FIG. 5, and 252d and 262d of FIG. 6) or a distance between the etching holes for forming the via holes (252a and 262a of FIGS. 3, 252b and 262b of FIGS. 4, 252c and 262c of FIG. 5, and 252d and 262d of FIG. 6), the thicknesses or materials of the first lower electrode 230, the second lower electrode 240, and the insulating layers 330 and 340, a etching process time or temperature of the etching process, and the like in the semiconductor etching process, and the variables randomly electrically connect or cut off the first upper electrode 210 and the second upper electrode 220. Accordingly, the variables are appropriately adjusted and controlled to implement N unit cells 11₁ to 11_{N} for acquiring the identification value of N bits in which 0 and 1 are even.

In the case of verifying the evenness of 0 and 1, the identification value generator or the identification value extractor is manufactured as a prototype by arraying multiple identification value generating elements depending on design and process values in which parameters are differentiated at low process cost by using a multi-project wafer (MPW) process before a production process through a single run to verify the evenness of 0 and 1, and after the evenness is verified, parameters in which the evenness of 0 and 1 is secured are selected and applied to the production process to implement the unit cells 11₁ to 11_{N} that evenly output 0 and 1.

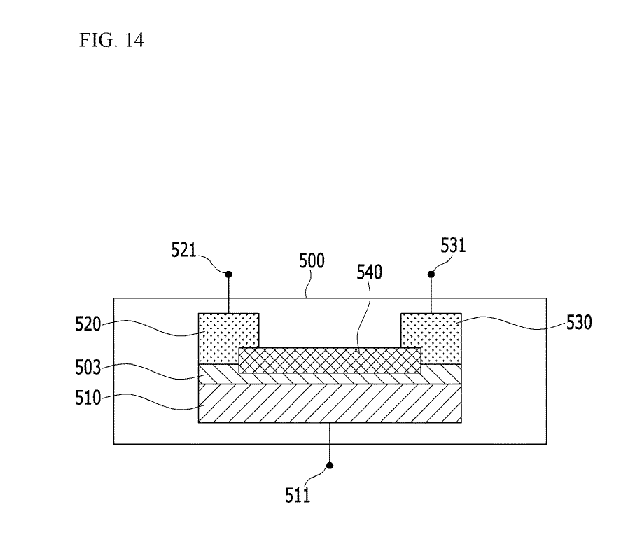

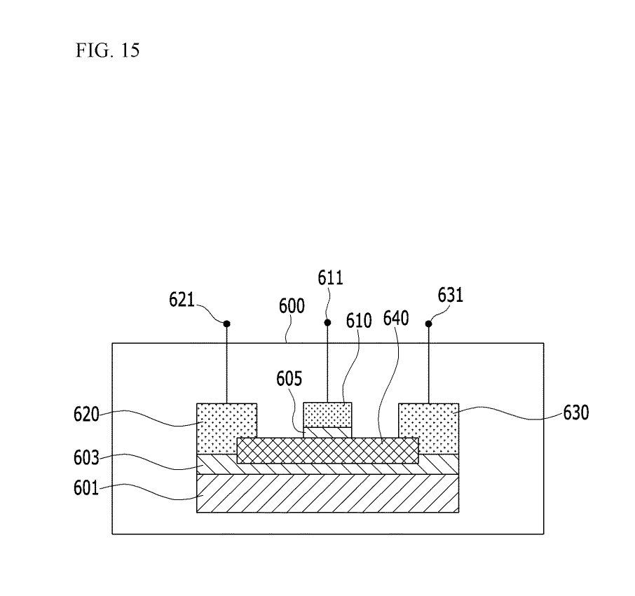

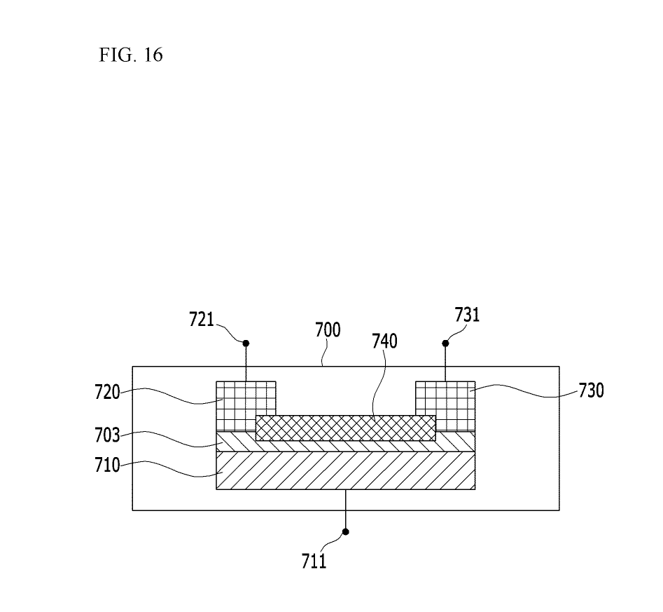

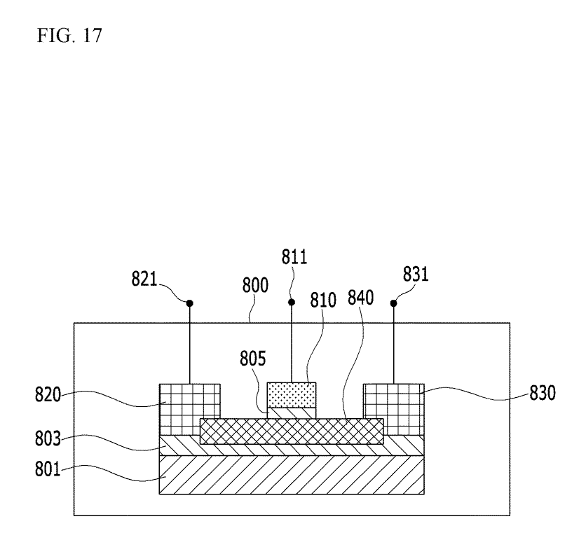

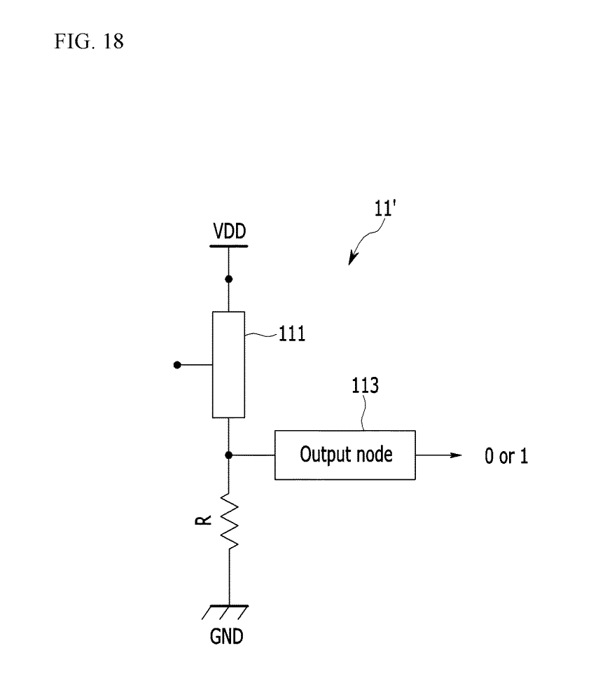

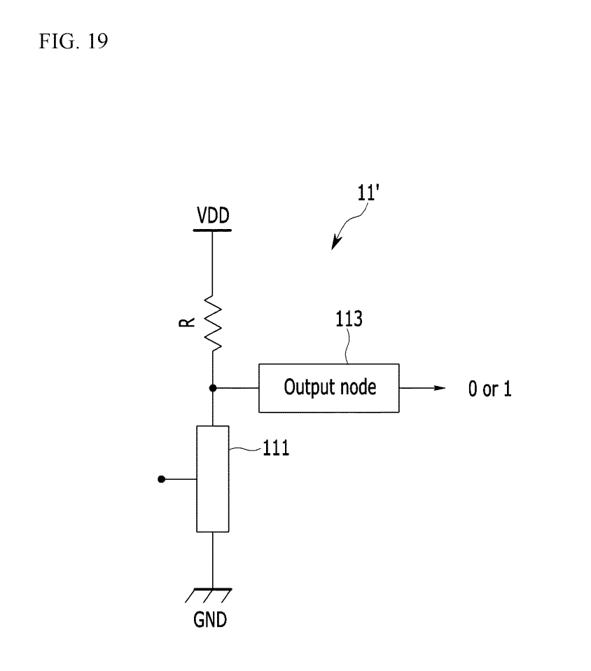

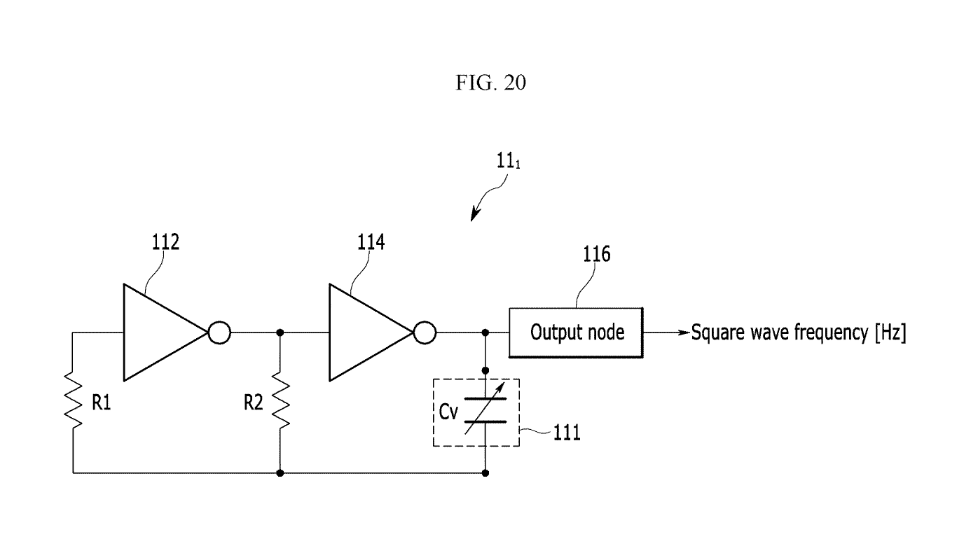

Meanwhile, the identification value generating elements 200 illustrated in FIGS. 7 to 10 may perform a function of a capacitor of an electronic component because the second lower electrode 240, the insulating layer 330, and the first lower electrode 230 are sequentially laminated. In this case, capacitance values between the first upper electrodes 210 and the second upper electrodes 220 in the identification value generating elements 200 illustrated in FIGS. 7 to 10 have different values. The unit cells 11₁ to 11_{N} using such a characteristic will be described with reference to FIG. 20.

FIG. 20 is a diagram illustrating a unit cell according to another exemplary embodiment of the present invention.

Referring to FIG. 20, the unit cell 11₁ includes an identification value generating element 111, inverters 112 and 114, resistors R1 and R2, and an output node 116. The identification value generating element 111 may be one of the identification value generating elements 200 described in FIGS. 7 to 10. The unit cell 11₁ operates as an oscillating circuit, and outputs a square wave frequency f[HZ] of 1/(2.2R₂Cv) through the output node 116. In FIG. 20, Cv represents a capacitance value of the identification value generating element 111.

The square wave frequency value output from the unit cell 11₁ is sampled at a desired time to be used to generate a fixed binary digital value, and may be used as a clock required to drive a digital circuit.

In this case, the capacitance values between the first upper electrode 210 and the second upper electrode 220 may be implemented to have different values in the identification value generating elements 111 of N unit cells 11₁ to 11_{N}.

The capacitance value between the first upper electrode 210 and the second upper electrode 220 is determined as shown in Equation 1.

C=∈*A/t (Equation 1)

Here, ∈ represents a dielectric constant of a material between the first upper electrode 210 and the second upper electrode 220, A represents an area between the first upper electrode 210 and the second upper electrode 220, and t represents an interval between the first upper electrode 210 and the second upper electrode 220.

As described above, the variables may include the sizes of etching holes for forming the via holes (252a and 262a of FIGS. 3, 252b and 262b of FIGS. 4, 252c and 262c of FIG. 5, and 252d and 262d of FIG. 6) or a distance between the etching holes for forming the via holes (252a and 262a of FIGS. 3, 252b and 262b of FIGS. 4, 252c and 262c of FIG. 5, and 252d and 262d of FIG. 6), the thicknesses or materials of the first lower electrode 230, the second lower electrode 240, and the insulating layers 330 and 340, a etching process time or temperature of the etching process, and the like in the semiconductor etching process, and the capacitance value between the first upper electrode 210 and the second upper electrode 220 may be randomly determined. Therefore, the variables are appropriately adjusted and controlled to implement the capacitance values between the first upper electrode 210 and the second upper electrode 220 to be different from each other in the identification value generating elements 111 of N unit cells 11₁ to 11_{N}. In addition, verifying the capacitance values between the first upper electrode 210 and the second upper electrode 220 of N unit cells 11₁ to 11_{N} may also be tested by using the MPW process.

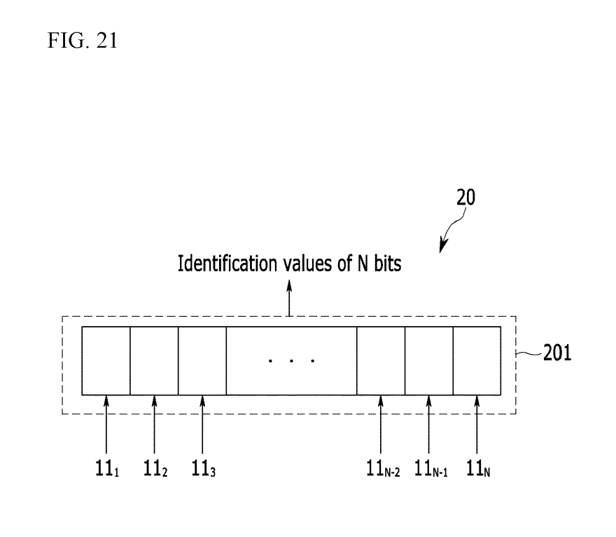

FIG. 21 is a diagram illustrating an identification value extractor according to an exemplary embodiment of the present invention.

Referring to FIG. 21, the identification value extractor 20 includes an input/output unit 201.

The input/output unit 201 receives binary digital values output from the plurality of unit cells 11₁ to 11_{N} of the identification value generator 10, respectively, as inputs to output identification values of N bits. In this case, the plurality of unit cells 11₁ to 11_{N} may be constituted like the unit cells illustrated in FIG. 18, and the unit cells illustrated in FIG. 19 and the unit cells illustrated in FIGS. 18 and 19 may be mixedly constituted.

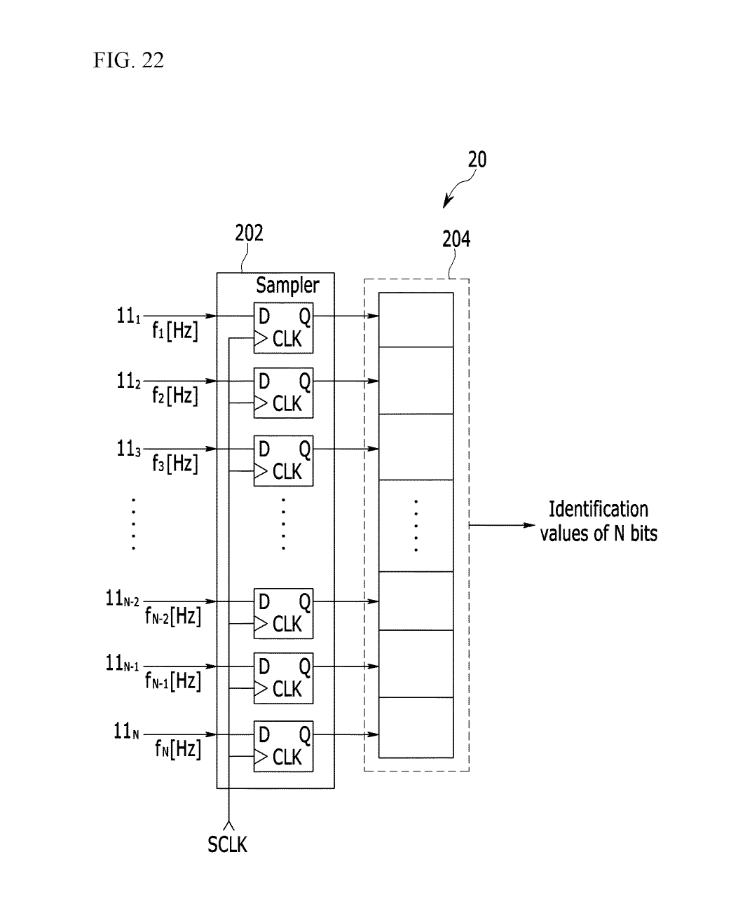

Meanwhile, when the plurality of unit cells 11₁ to 11_{N} are constituted as illustrated in FIG. 20, the identification value extractor 20 needs to sample the square wave frequency values output from the plurality of unit cells 11₁ to 11_{N}, respectively, in order to generate the identification value of N bits. When the plurality of unit cells 11₁ to 11_{N}, are constituted as illustrated in FIG. 20, the identification value extractor 20 will be described with reference to FIG. 22.

FIG. 22 is a diagram illustrating an identification value extractor according to another exemplary embodiment of the present invention.

Referring to FIG. 22, the identification value extractor 20 includes a sampler 202 and an output unit 204.

The sampler 202 includes a plurality of D flip-flops receiving the square wave frequency values f₁ to f_{N} output from the plurality of unit cells 11₁ to 11_{N}, respectively, as inputs.

Each of the plurality of D flip-flops has an input terminal D, and an output terminal Q and a clock terminal CLK, and in the case where a clock signal SCLK is applied to the clock terminal CLK, when an input signal input into the input terminal D is 1, 1 is output through the output terminal Q, and when the input signal input into the input terminal D is 0, 0 is output through the output terminal Q.

When the clock signal SCLK is input into the clock terminal CLK at the time of desired sampling, the plurality of D flip-flops output a binary digital value corresponding to a frequency value at the time among the square wave frequency values f1 to fN output from the plurality of unit cells 11₁ to 11_{N}, respectively, to the output unit 204 through the output terminal Q.

The output unit 204 receives the binary digital values output from the plurality of D flip-flops, respectively, as inputs to output the identification value of N bits.

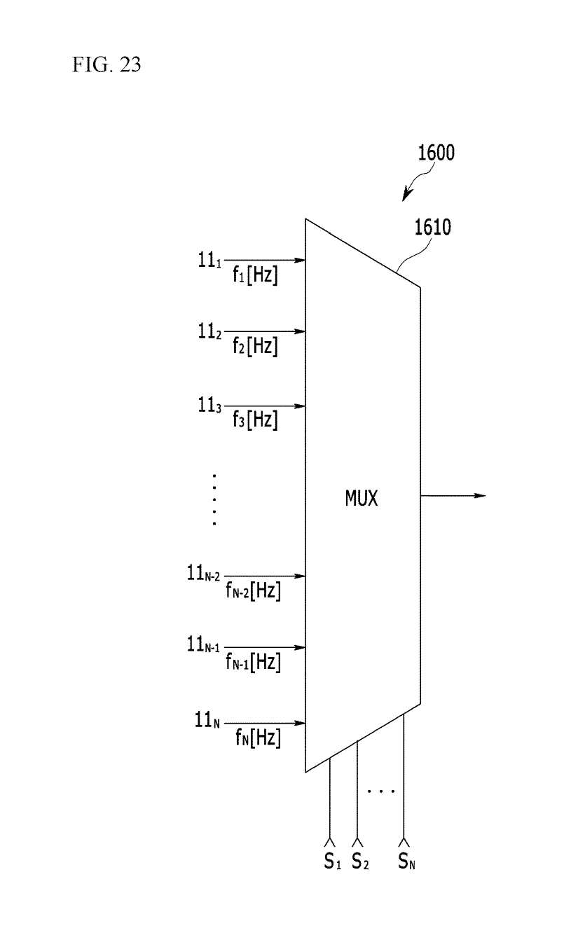

FIG. 23 is a diagram illustrating one example of a variable frequency extracting apparatus which can be implemented by using an identification value generator according to the exemplary embodiment of the present invention.

Referring to FIG. 23, the variable frequency extracting device 1600 includes a multiplexer (MUX) 1610 that receives the square wave frequency values f₁ to f_{N} output from the plurality of unit cells 11₁ to 11_{N}, respectively, as the inputs to select and output one square wave frequency value.

The multiplexer 1610 selects and outputs one square wave frequency value among the plurality of square wave frequency values f₁ to f_{N} according to selection values S₁ to S_{N} input through a selection value input terminal. When one square wave frequency value is used, a clock required to drive the digital circuit may be easily changed to a desired frequency value.

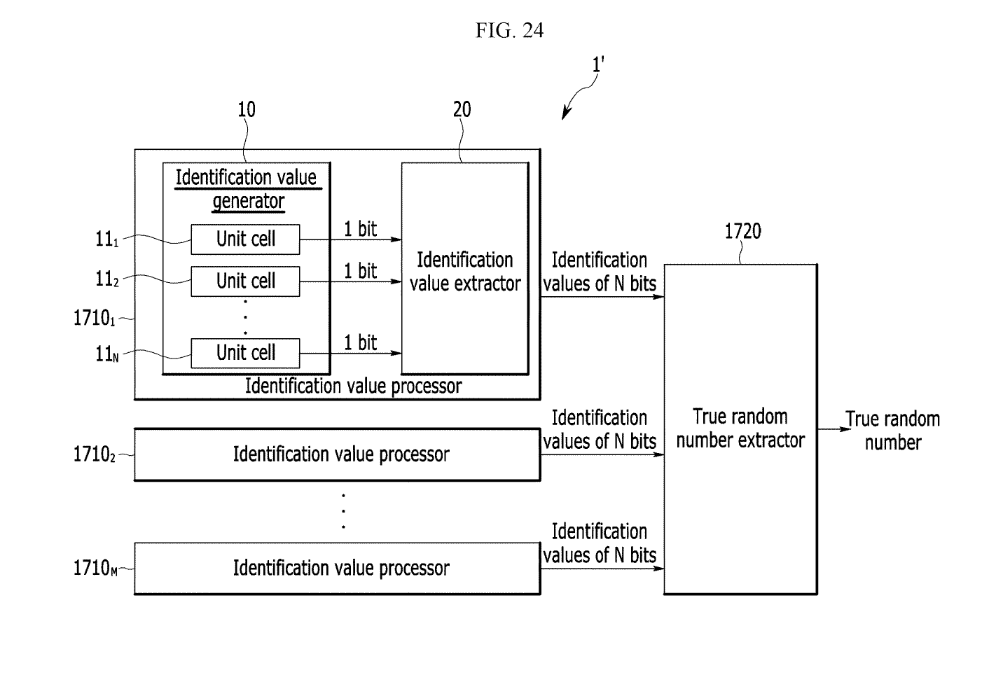

FIG. 24 is a diagram illustrating an apparatus for generating a digital value according to another exemplary embodiment of the present invention.

Referring to FIG. 24, the digital value generating apparatus 1′ may include a plurality of identification value processors 1710₁ to 1710_{M} and a true random number extractor 1720. Herein, each of the identification value processors 1710₁ to 1710_{M} includes the identification value generator 10 and the identification value extractor 20 described above. In FIG. 24, it is illustrated that only the identification value processor 1710₁ includes the identification value generator 10 and the identification value extractor 20 for easy description, but the residual identification value processors 1710₂ to 1710_{M} may also be constituted like the identification value processor 1710₁.

Each of the identification value processors 1710₁ to 1710_{M} outputs the identification value of N bits to the true random number extractor 1720.

The true random number extractor 1720 extracts a true random number by using the identification values of N bits output from the identification value processors 1710₁ to 1710_{M}, respectively. The true random number extractor 1720 may extract the true random number by sequentially extracting the identification values of N bits outputted from the identification value processors 1710₁ to 1710_{M}, respectively. Alternatively, the true random number extractor 1720 may extract the true random number by randomly extracting one or multiple identification values of N bits among M identification values of N bits. The true random number extractor 1720 outputs the generated true random number.

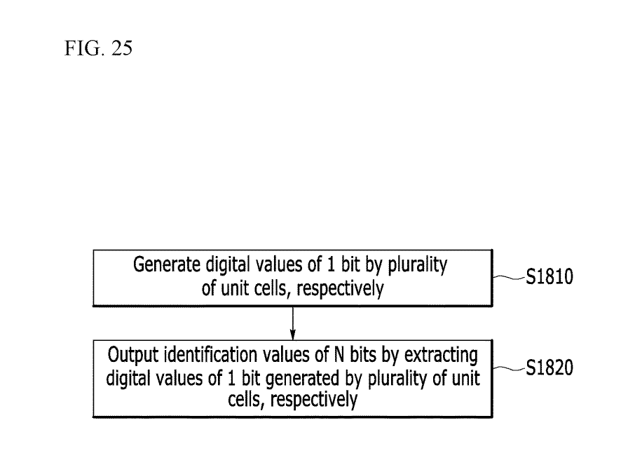

FIG. 25 is a flowchart illustrating a method for generating a digital value according to an exemplary embodiment of the present invention.

Referring to FIG. 25, the digital value generating apparatus 1 generates a digital value of 1 bit by the plurality of respective unit cells 11₁ to 11_{N} including the identification value generating elements described above, respectively (S1810). Meanwhile, when the plurality of unit cells 11₁ to 11_{N} are constituted as illustrated in FIG. 20, the digital value generating apparatus 1 may sample the square wave frequency values output from the plurality of unit cells 11₁ to 11_{N}, respectively, and generate the digital value of 1 bit corresponding to the frequency value at the sampling time.

The digital value generating apparatus 1 extracts digital values of 1 bit generated by the plurality of unit cells 11₁ to 11_{N}, respectively, to output the identification values of N bits (S1820).

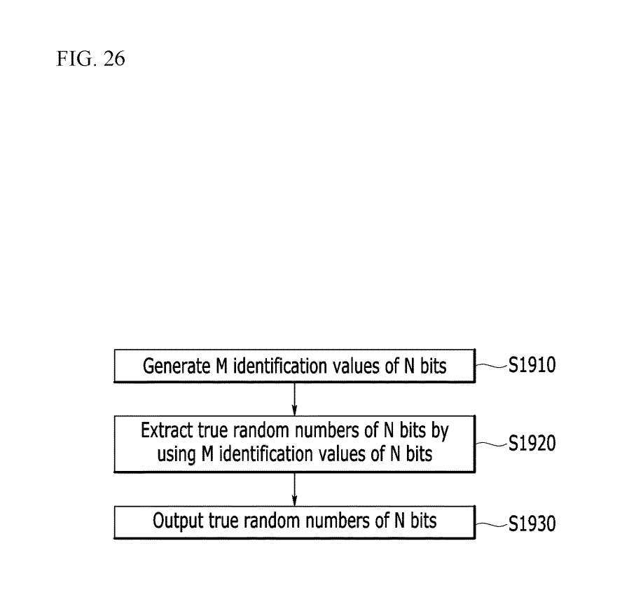

FIG. 26 is a flowchart illustrating a method for generating a digital value according to another exemplary embodiment of the present invention.

Referring to FIG. 26, the digital value generating apparatus 1′ generates M identification values of N bits by using the plurality of identification value processors 1710₁ to 1710_{M} (S1910).

The digital value generating apparatus 1′ extracts a true random number of N bits by using M identification values of N bits (S1920). As a method for extracting the true random number of N bits by using M identification values of N bits, various methods may be used.

The digital value generating apparatus 1′ outputs the extracted true random number of N bits (S1930).

According to exemplary embodiments of the present invention, via holes are randomly generated due to a deviation of an etching process and a difference in etching depths, a binary digital value which cannot be predicted can be generated by forming vias in the via holes and applying power, and a random binary digital value may be output every sampling at a desired time. Further, a random variable frequency value may be output.

In addition, the binary digital value which cannot be predicted can be generated from a conductor property, a semiconductor property, and a P- or N-type semiconductor property of a carbon nanotube and a random layout of the carbon nanotube.

As such, after the binary digital identification value which cannot be predicted is generated, the value is fixed to be appropriate for use as an identification value.

In addition, the variable frequency value which cannot be predicted can be used for power analysis attack for information dispossession or as a clock source required for constituting a general digital low power circuit.

Further, since the binary digital value is physically randomly determined as 0 or 1, true randomness of the generated identification value is secured, and as a result, it is difficult to anticipate the generated identification value, thereby the generated identification value may robust against an attack for dispossessing the generated identification value.

Moreover, a manufacturing process is simple and physical clone is impossible, and as a result, security of the identification value or a true random number is high. In addition, when identification value generating elements or identification value generators are designed with the minimum number and the elements or units are copied and simply arrayed, the identification value and the true random number or a frequency oscillator can be simply made.

The exemplary embodiments of the present invention are not embodied only by the apparatus and/or the method described above, and the above-mentioned exemplary embodiments may be embodied by a program performing functions which correspond to the configuration of the exemplary embodiments of the present invention, or a recording medium on which the program is recorded. These embodiments can be easily devised from the description of the above-mentioned exemplary embodiments by those skilled in the art to which the present invention pertains.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An apparatus for generating a digital value, the apparatus comprising:
an identification value generator including a plurality of unit cells; and
an identification value extractor outputting identification values of a plurality of bits by using output values of the plurality of unit cells,
wherein each of the plurality of unit cells includes an identification value generating element including a first upper electrode and a second upper electrode formed on the same layer, and determines the output value according to electrical connection or cut-off of the first upper electrode and the second upper electrode.

2. The apparatus of claim 1, wherein
the electrical connection or cut-off is determined by a difference in etching depth between via holes formed in the lower direction of the first upper electrode and the second upper electrode through etching, respectively.

3. The apparatus of claim 2, wherein
the identification value generating element includes:
a first insulating layer formed on a substrate;
a second lower electrode formed on the first insulating layer;
a second insulating layer formed on the second lower electrode;
a first lower electrode formed on the second insulating layer;
a third insulating layer formed on the first lower electrode;
a first via hole and a second via hole formed in the lower direction of the third insulating layer with set depths, respectively, through an etching process;
a first via and a second via formed by filling the first via hole and the second via hole with conductors, respectively; and
the first upper electrode and the second upper electrode are formed on the first via and the second via.

4. The apparatus of claim 3, wherein
the first via hole and the second via hole are formed with different depths through the etching process.

5. The apparatus of claim 4, wherein:
when both the first via and the second via reach locations of the second lower electrode, the first upper electrode and the second upper electrode are electrically connected; and
when only one of the first via and the second via reaches the first lower electrode or the second lower electrode, the first upper electrode and the second upper electrode are electrically cut off.

6. The apparatus of claim 5, wherein
some of the plurality of unit cells include identification value generating elements in which the first upper electrode and the second upper electrode are electrically connected, and the residual of the plurality of unit cells include identification value generating elements in which the first upper electrode and the second upper electrode are electrically cut off.

7. The apparatus of claim 1, wherein
the identification value generating element further includes a carbon nanotube layer formed to connect the first upper electrode and the second upper electrode, and
the electrical connection or cut-off is determined by the carbon nanotube layer.

8. The apparatus of claim 7, wherein
the carbon nanotube layer includes a single carbon nanotube or a carbon nanotube bundle.

9. The apparatus of claim 7, wherein
the first upper electrode and the second upper electrode are formed by one of a P-type semiconductor, an N-type semiconductor, and a conductive material.

10. The apparatus of claim 7, wherein
the identification value generating element further includes
an insulating layer formed on the substrate and having the first upper electrode and the second upper electrode formed on the top thereof to be spaced apart from each other, and
a control electrode formed on an insulating layer on the carbon nanotube layer or formed on the substrate.

11. The apparatus of claim 3, wherein
each of the plurality of unit cells includes an oscillating circuit outputting a square wave frequency as the output value by using the identification value generating element as a capacitor.

12. The apparatus of claim 11, wherein
the identification value extractor includes
a sampler outputting a plurality of binary digital values by sampling square wave frequencies output from the plurality of unit cells, respectively, at a desired time, and
an output unit outputting the identification values of the plurality of bits from the plurality of binary digital values.

13. The apparatus of claim 12, wherein
the sampler includes a plurality of D flip-flops receiving the square wave frequencies output from the plurality of unit cells, respectively, as inputs, and outputting 0 or 1 from a value of a square wave frequency when a clock signal is applied.

14. The apparatus of claim 1, wherein
each of the plurality of unit cells includes:
the identification value generating element connected between a first voltage source supplying a first voltage and a second voltage source supplying a second voltage lower than the first voltage; and
an output node outputting 0 or 1 as the output value according to the electrical connection or cut-off of the identification value generating element, and
the first upper electrode is connected to the first voltage source, the second upper electrode is connected to the second voltage source, and the output node is connected to the first upper electrode or the second upper electrode.

15. An apparatus for generating a digital value, the apparatus comprising:
a plurality of identification value processors including a plurality of unit cells, respectively, and outputting identification values of a plurality of bits through output values of the plurality of unit cells; and
a true random number extractor extracting true random numbers by using a plurality of identification values output from the plurality of identification value processors, respectively, and outputting the extracted true random numbers,
wherein each of the plurality of unit cells includes an identification value generating element determining the output value according to electrical connection or cut-off of a first upper electrode and a second upper electrode formed on the same layer.

16. The apparatus of claim 15, wherein
the identification value generating element includes:
a first insulating layer formed on a substrate;
a second lower electrode formed on the first insulating layer;
a second insulating layer formed on the second lower electrode;
a first lower electrode formed on the second insulating layer;
a third insulating layer formed on the first lower electrode;
a first via hole and a second via hole formed in the lower direction of the third insulating layer with set depths, respectively, through an etching process; and
a first via and a second via formed by filling the first via hole and the second via hole with a conductor, respectively,
wherein the first upper electrode and the second upper electrode are formed on the first via and the second via, and
the first via hole and the second via hole are formed with different depths through the etching process.

17. The apparatus of claim 15, wherein
the identification value generating element includes:
an insulating layer formed on the substrate and having the first upper electrode and the second upper electrode formed on the top thereof to be spaced apart from each other;
a carbon nanotube layer formed to connect the first upper electrode and the second upper electrode on the insulating layer and including a single carbon nanotube or a carbon nanotube bundle; and
a control electrode formed on an insulating layer on the carbon nanotube layer or formed on the substrate.

18. The apparatus of claim 17, wherein
the first upper electrode and the second upper electrode are formed by one of a P-type semiconductor, an N-type semiconductor, and a conductive material.

19. A method for generating a digital value in a digital value generating apparatus, the method comprising:
generating a plurality of output values by using a plurality of unit cells including identification value generating elements determining output values, respectively, according to electrical connection or cut-off between a first upper electrode and a second upper electrode formed on the same layer; and
outputting identification values of a plurality of bits by using the plurality of output values,
wherein the electrical connection or cut-off is determined by a difference in etching depth between via holes formed in the lower direction of the first upper electrode and the second upper electrode through etching, respectively, or a carbon nanotube layer formed to connect the first upper electrode and the second upper electrode.

20. The method of claim 19, further comprising:
generating a plurality of identification values of the plurality of bits; and
extracting a true random number of a predetermined bit by using the plurality of identification values.
